(19) United States
(12) Patent Application Publication
(10) Pub. No.: US 2025/0377394 A1
(43) Pub. Date: Dec. 11, 2025

(54) HIGH-FREQUENCY CIRCUIT AND ABNORMALITY DETECTION METHOD THEREOF

(71) Applicant: ANRITSU CORPORATION, Kanagawa (JP)

(72) Inventor: Suguru FUJITA, Kanagawa (JP)

(21) Appl. No.: 19/204,763

(22) Filed: May 12, 2025

(30) Foreign Application Priority Data
Jun. 7, 2024 (JP) 2024-092700

(51) Int. Cl. G01R 29/08

(52) U.S. Cl. CPC G01R 29/0871

(57) ABSTRACT

A high-frequency circuit includes a capacitor connected to a main line of a transmission line, a resistor connected in parallel between two terminals of the capacitor, and bias terminals connected to the main line, disposed on both outsides of an inspection circuit that includes the resistor and the capacitor, and connected to a measurement device in a case of abnormality diagnosis, in which the measurement device applies a direct current voltage or a direct current to the inspection circuit through the bias terminals, measures at least one kind of measurement value of a resistance value, a voltage, and a current between the bias terminals, and detects whether or not at least one kind of abnormality including disconnection of the main line or short circuit of the capacitor occurs based on the measurement value.

### TECHNICAL FIELD

The present invention relates to a high-frequency circuit and an abnormality detection method thereof, and particularly to a high-frequency circuit for a frequency band from a microwave band to a terahertz band and an abnormality detection method thereof.

### BACKGROUND ART

In the related art, for example, a high-frequency circuit, such as an amplifier or a mixer, for a frequency band from a microwave band to a terahertz band is used, and it is required to detect disconnection of a high-frequency signal transmission line and failure of a semiconductor such as a capacitor or a transistor, which are included in the high-frequency circuit.

FIG. 9 is a diagram showing an example of a configuration of a high-frequency circuit according to the related art. As shown in FIG. 9, a partial discharge detection device 70 disclosed in Patent Document 1 includes a sensor 71 that detects an electromagnetic wave of a partial discharge, a sensor matching resistor 72, a cable 73, a parallel circuit consisting of a filter 74 including a capacitor that is inserted in series with a signal line and a switch 75, a potential forming circuit that has input resistors 76 and 77 and a circuit power supply 78 and forms a potential at point A, and a partial discharge determination/self-diagnosis circuit 81 that, after controlling the switch 75 to a closed circuit state in a case of self-diagnosis, determines an abnormality such as deviation of the sensor matching resistor 72 or disconnection of the cable 73 based on the potential at point A.

In addition, Patent Document 1 discloses that, by performing self-diagnosis by outputting a simulated pulse signal 86 to a simulated pulse generation device 82 under control of a partial discharge determination/self-diagnosis circuit 81, it is possible to detect an abnormality such as deviation of the sensor matching resistor based on an input portion potential, and to perform self-diagnosis on the integrity of the device by controlling the switch 75 to the closed circuit state to ensure direct current conduction with respect to a signal line in a case of self-diagnosis.

### RELATED ART DOCUMENT

### Patent Document

[Patent Document 1] JP-A-2010-276420

### DISCLOSURE OF THE INVENTION

### Problem that the Invention is to Solve

However, in the related art as disclosed in Patent Document 1, there is a problem in that a circuit area increases by disposing a switch circuit and a circuit that controls the switch circuit in parallel with a circuit including a capacitor.

The present invention has been made in order to solve such a problem of the related art, and an object of the present invention is to provide a high-frequency circuit capable of detecting an abnormality such as disconnection of a transmission line for a high-frequency signal with a small configuration, and an abnormality detection method thereof.

### Means for Solving the Problem

In order to solve the above problems, according to the present invention, there is provided a high-frequency circuit (1, 2) in which a transmission line (10) for transmitting a high-frequency signal is provided on a dielectric substrate (100), the high-frequency circuit including: an electronic component (32, 34, 35) that has a plurality of terminals connected to a main line (12 to 17) of the transmission line; a resistor (25, 26) that is connected in parallel between two terminals, through which a direct current does not flow, among the plurality of terminals of the electronic component; and a pair of measurement terminals (41a, 42a, 43a, 44a) that are connected to the main line, disposed respectively at both outsides of an inspection circuit (50, 52) which includes the resistor and the electronic component, and connected to a measurement device (60) in a case of abnormality diagnosis, in which the measurement device includes a measurement circuit (61) that applies a direct current voltage or a direct current to the inspection circuit through the pair of measurement terminals and measures at least one kind of a measurement value of a resistance value between the pair of measurement terminals, a voltage between the pair of measurement terminals, and a current flowing between the pair of measurement terminals, and an abnormality detection unit (62) that detects whether or not disconnection of the main line or short circuit of the electronic component occurs, based on the measurement value measured by the measurement circuit.

With this configuration, the high-frequency circuit according to the embodiment of the present invention can detect whether or not at least one kind of abnormality including disconnection of the main line of the transmission line in the inspection circuit or short circuit of an electronic component occurs with a small configuration.

In addition, the high-frequency circuit according to the embodiment of the present invention has an advantage that the abnormality can be detected only by direct current measurement without using an expensive high-frequency measurement device.

In addition, in the high-frequency circuit according to the present invention, the inspection circuit may further include a first branch line (21, 23) that branches from the main line and connects one terminal of the two terminals of the electronic component to one end of the resistor, and a second branch line (22, 24) that branches from the main line and connects the other terminal of the two terminals of the electronic component to the other end of the resistor, and a line length of the first branch line and the second branch line from the main line to the resistor may be an integer multiple of substantially ½ of a wavelength of the high-frequency signal transmitted through the first branch line and the second branch line.

With this configuration, in the high-frequency circuit according to the embodiment of the present invention, the impedance of the path consisting of the resistor, the first branch line, and the second branch line can be made sufficiently high as viewed from the main line of the transmission line, so that the pass gain of the entire high-frequency circuit is not adversely affected.

In addition, in the high-frequency circuit according to the present invention, the main line may include a first main line (14) and a second main line (15) that are capacitively coupled to each other via the electronic component, a first main line conductor of the first main line, a second main line conductor of the second main line, a first branch conductor of the first branch line, and a second branch conductor of the second branch line may be provided on a surface of the dielectric substrate, the high-frequency circuit may further include a metal layer (301) that is provided above the dielectric substrate, an air bridge (303) that connects the first main line conductor to the metal layer, and a dielectric film (304) that is provided between the second main line conductor and the metal layer, the first branch conductor may be integrally formed with the first main line conductor, the second branch conductor may be integrally formed with the second main line conductor, and the electronic component may be a capacitor (32) that includes the metal layer serving as the one terminal, the dielectric film, and the second main line conductor serving as the other terminal.

In addition, in the high-frequency circuit according to the present invention, the main line may include a first main line (14) and a second main line (15) that are capacitively coupled to each other via the electronic component, a first main line conductor of the first main line and a second main line conductor of the second main line may be provided on a surface of the dielectric substrate, the high-frequency circuit may further include a first metal wire (312) that is provided below the first main line conductor, a second metal wire (313) that is provided below the second main line conductor, a metal layer (311) that is provided above the first metal wire and the second metal wire, a dielectric film (319) that is provided between the second metal wire and the metal layer, a first via hole (316) that connects the first main line conductor to the first metal wire, a second via hole (317) that connects the second main line conductor to the second metal wire, and a third via hole (318) that connects the first metal wire to the metal layer, a first branch conductor of the first branch line conductor provided below the first main line conductor may be integrally formed with the first metal wire, a second branch conductor of the second branch line conductor provided below the second main line conductor may be integrally formed with the second metal wire, the electronic component may be a capacitor (32) that includes the metal layer serving as the one terminal, the dielectric film, and the second metal wire serving as the other terminal, and the abnormality detection unit may further detect whether or not any of the first metal wire, the second metal wire, the first via hole, and the second via hole is disconnected.

With this configuration, in the high-frequency circuit according to the present invention, the abnormality detection unit can detect whether or not any of the first via hole, the second via hole, the first metal wire, or the second metal wire is disconnected.

In addition, in the high-frequency circuit according to the present invention, the main line may include a first main line (12) that is connected to the one terminal of the electronic component and a second main line (13) that is connected to the other terminal of the electronic component, a first main line conductor of the first main line and a second main line conductor of the second main line may be provided on a surface of the dielectric substrate, the high-frequency circuit may further include a first metal wire (321) that is provided below the first main line conductor, a second metal wire (322) that is provided below the second main line conductor, a third metal wire (325) that is provided below the first metal wire, a fourth metal wire (326) that is provided below the second metal wire, a fifth metal wire (329) that is provided below the third metal wire and connected to the one terminal, a sixth metal wire (330) that is provided below the fourth metal wire and connected to the other terminal, and a plurality of via holes (331 to 336) that connect the first main line conductor, the first metal wire, the third metal wire, and the fifth metal wire to each other, and connect the second main line conductor, the second metal wire, the fourth metal wire, and the sixth metal wire to each other, a first branch conductor of the first branch line provided below the third metal wire may be integrally formed with the fifth metal wire, a second branch conductor of the second branch line provided below the fourth metal wire may be integrally formed with the sixth metal wire, the electronic component may be an emitter-grounded transistor (34, 35) in which the one terminal is a base and the other terminal is a collector, and the abnormality detection unit may further detect whether or not any of the first metal wire, the second metal wire, the third metal wire, the fourth metal wire, the fifth metal wire, the sixth metal wire, and the plurality of via holes is disconnected.

With this configuration, in the high-frequency circuit according to the present invention, the abnormality detection unit can detect whether or not any of the first via hole, the second via hole, the third via hole, the fourth via hole, the fifth via hole, the sixth via hole, the first metal wire, the second metal wire, the third metal wire, the fourth metal wire, the fifth metal wire, or the sixth metal wire is disconnected.

In addition, according to the present invention, there is provided an abnormality detection method of a high-frequency circuit (1, 2), in which a transmission line (10) for transmitting a high-frequency signal is provided on a dielectric substrate (100), including an electronic component (32, 34, 35) that has a plurality of terminals connected to a main line (12 to 17) of the transmission line; a resistor (25, 26) that is connected in parallel between two terminals, through which a direct current does not flow, among the plurality of terminals of the electronic component; and a pair of measurement terminals (41a, 42a, 43a, 44a) that are connected to the main line, disposed respectively at both outsides of an inspection circuit (50, 52) which includes the resistor and the electronic component, and connected to a measurement device (60) in a case of abnormality diagnosis, in which the measurement device includes a measurement circuit (61) that applies a direct current voltage or a direct current to the inspection circuit through the pair of measurement terminals and measures at least one kind of a measurement value of a resistance value between the pair of measurement terminals, a voltage between the pair of measurement terminals, and a current flowing between the pair of measurement terminals, and an abnormality detection unit (62) that detects whether or not disconnection of the main line or short circuit of the electronic component occurs, based on the measurement value measured by the measurement circuit.

### Advantage of the Invention

The present invention provides a high-frequency circuit capable of detecting an abnormality such as disconnection of a transmission line for a high-frequency signal with a small configuration, and an abnormality detection method thereof.

### BRIEF DESCRIPTION OF THE DRAWINGS

FIG. 1 is a diagram showing a configuration of a high-frequency circuit according to a first embodiment of the present invention.

FIG. 2A is a graph showing a pass characteristic S₂₁ of a high-frequency circuit in a normal case, and FIG. 2B is a graph showing the pass characteristic S₂₁ of the high-frequency circuit in an abnormal case.

FIG. 3 is a diagram showing a configuration of a high-frequency circuit in an abnormal case.

FIG. 4A is a top view of an inspection circuit provided in the high-frequency circuit according to the first embodiment of the present invention, FIG. 4B is a cross-sectional view taken along line A-A of FIG. 4A, and FIG. 4C is a cross-sectional view taken along line B-B of FIG. 4A.

FIG. 5A is a graph showing a pass characteristic S₂₁ of the high-frequency circuit in a case where a line length of a first branch line and a second branch line in the inspection circuit is set to ¼ of the wavelength of a high-frequency signal, and FIG. 5B is a graph showing a pass characteristic S₂₁ of the high-frequency circuit in a case where the line length of the first branch line and the second branch line in the inspection circuit is set to ½ of the wavelength of the high-frequency signal.

FIG. 6A is a top view showing another configuration example of the inspection circuit, FIG. 6B is a cross-sectional view taken along line A-A of FIG. 6A, and FIG. 6C is a cross-sectional view taken along line B-B of FIG. 6A.

FIG. 7 is a diagram showing a configuration of a high-frequency circuit according to a second embodiment of the present invention.

FIG. 8A is a top view of an inspection circuit provided in the high-frequency circuit according to the second embodiment of the present invention, and FIG. 8B is a cross-sectional view taken along line A-A of FIG. 8A.

FIG. 9 is a diagram showing a configuration of a high-frequency circuit in the related art.

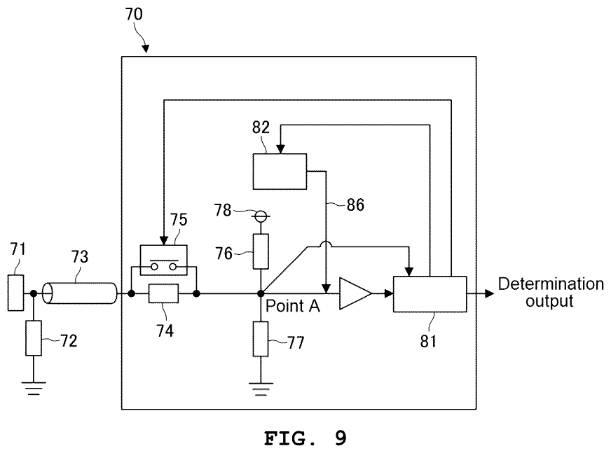

### BEST MODE FOR CARRYING OUT THE INVENTION

Hereinafter, embodiments of a high-frequency circuit and an abnormality detection method of the present invention will be described with reference to the drawings. The high-frequency circuit according to the embodiment of the present invention is for amplifying, for example, a high-frequency signal exceeding 200 GHZ.

### First Embodiment

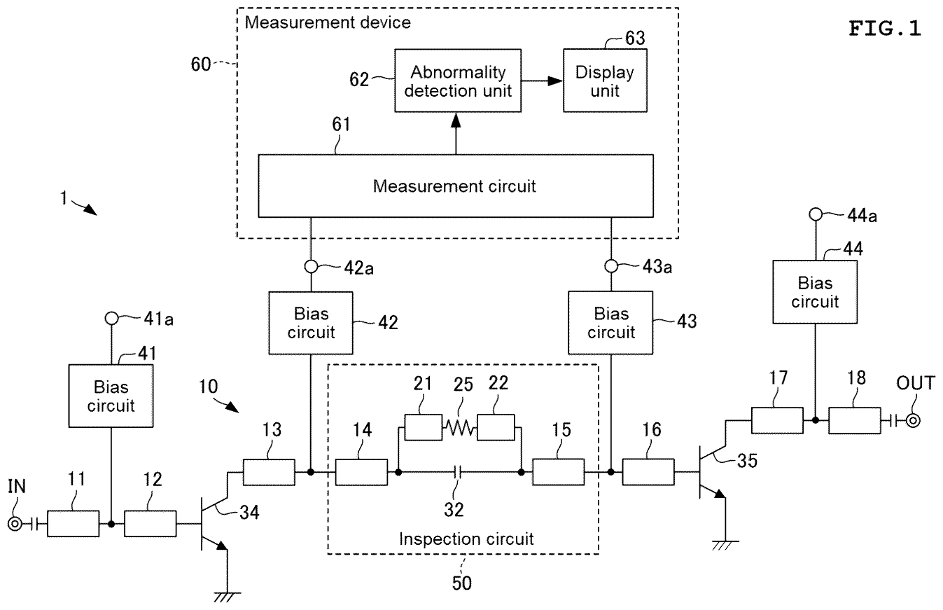

First, a configuration of a high-frequency circuit according to a first embodiment of the present invention will be described with reference to FIGS. 1 to 6C.

FIG. 1 is a diagram showing a configuration of a high-frequency circuit 1 of the present embodiment. As shown in FIG. 1, the high-frequency circuit 1 includes an input terminal IN to which a high-frequency signal is input, an output terminal OUT that outputs the high-frequency signal, a transmission line 10 that connects from the input terminal IN to the output terminal OUT to transmit the high-frequency signal, a capacitor 32, transistors 34 and 35, bias circuits 41, 42, 43, and 44, bias terminals 41a, 42a, 43a, and 44a, an inspection circuit 50, and a measurement device 60.

The transmission line 10 is configured with main lines 11 to 18 and branch lines 21 and 22. The capacitor 32 for direct current blocking is inserted in series between the main line 14 as a first main line and the main line 15 as a second main line, and two terminals (electrodes) of the capacitor 32 are electrically connected to the main lines 14 and 15, respectively. A resistor 25 is connected in parallel between the two terminals of the capacitor 32. The capacitor 32 is an example of an electronic component provided in the high-frequency circuit 1, and the two terminals correspond to two terminals through which direct current does not flow.

The main lines 14 and 15, the branch line 21 as the first branch line, the branch line 22 as the second branch line, the resistor 25, and the capacitor 32 constitute the inspection circuit 50.

The transistors 34 and 35 are, for example, NPN type bipolar transistors and are emitter-grounded. That is, the high-frequency circuit 1 functions as an amplification circuit in which the emitter-grounded transistors 34 and 35 are connected in two stages.

The transistors 34 and 35 are not limited to NPN type bipolar transistors, and may be, for example, PNP type bipolar transistors or field effect transistors.

The bias circuit 41 is a circuit that supplies a bias voltage applied to the bias terminal 41a from a direct current power source (not shown) to the base of the transistor 34 in a case where the high-frequency circuit 1 is in a normal operation.

The bias circuit 42 is a circuit that supplies a bias voltage applied to the bias terminal 42a from a direct current power source (not shown) to the collector of the transistor 34 in a case where the high-frequency circuit 1 is in a normal operation.

The bias circuit 43 is a circuit that supplies a bias voltage applied to the bias terminal 43a from a direct current power source (not shown) to the base of the transistor 35 in a case where the high-frequency circuit 1 is in a normal operation.

The bias circuit 44 is a circuit that supplies a bias voltage applied to the bias terminal 44a from a direct current power source (not shown) to the collector of the transistor 35 in a case where the high-frequency circuit 1 is in a normal operation.

The bias circuits 41 to 44 are designed to have sufficiently high impedance to minimize the influence on the characteristics of the high-frequency circuit 1.

The bias circuit 41 and the bias terminal 41a are connected between the main lines 11 and 12 in the transmission line 10. The bias circuit 42 and the bias terminal 42a are connected between the main lines 13 and 14 in the transmission line 10. The bias circuit 43 and the bias terminal 43a are connected between the main lines 15 and 16 in the transmission line 10. The bias circuit 44 and the bias terminal 44a are connected between the main lines 17 and 18 in the transmission line 10.

That is, in the present embodiment, the bias terminals 42a and 43a are electrically connected to the main lines 14 and 15 via the bias circuits 42 and 43, respectively. The bias terminals 42a and 43a are disposed on both outsides of the main lines 14 and 15 constituting the inspection circuit 50, respectively, and serve as a pair of measurement terminals connected to the measurement device 60 in a case of abnormality diagnosis.

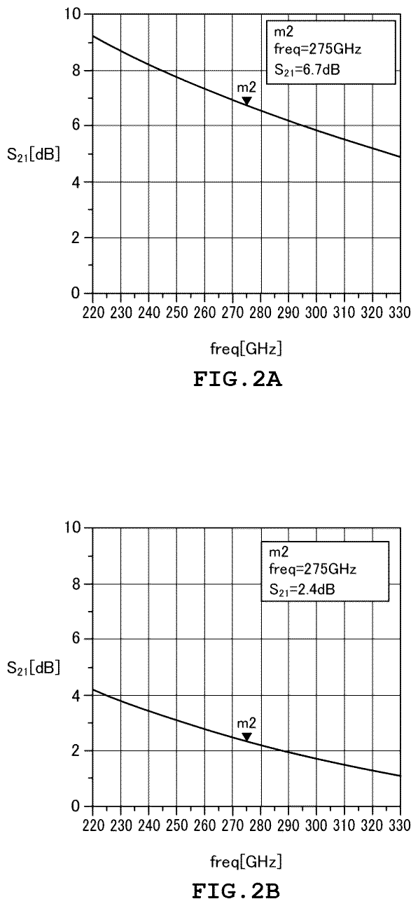

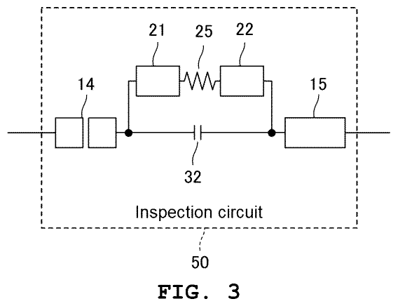

FIG. 2A is a graph showing a pass characteristic S₂₁ from the input terminal IN to the output terminal OUT of the high-frequency circuit 1 in a normal case. On the other hand, FIG. 2B shows the pass characteristic S₂₁ in an abnormal case where the main line 14 or the main line 15 in the inspection circuit 50 is disconnected as shown in FIG. 3. Here, it is assumed that the capacitance of the capacitor 32 is 1 pF and the resistance value of the resistor 25 is 1 kΩ.

In the graphs of FIG. 2A and FIG. 2B, in a case of focusing on, for example, 275 GHz in a frequency band of 220 GHz to 330 GHz used by the high-frequency circuit 1, it can be seen that the pass gain in a normal case is 6.7 dB, whereas the pass gain in the abnormal case is decreased to 2.4 dB.

As described above, in a case where the pass characteristic S₂₁ from the input terminal IN to the output terminal OUT is lower than that in a normal case, it is considered that some abnormality such as disconnection of the main lines 14 and 15 or the connection conductor, or short circuit of the capacitor 32 or the transistors 34 and 35 occurs.

The measurement device 60 performs measurement for making the cause of the abnormality clearer, for example, in a case where the abnormality is observed in the pass characteristic S₂₁ as described above, and includes a measurement circuit 61, an abnormality detection unit 62, and a display unit 63.

The measurement circuit 61 is connected to the bias terminals 42a and 43a in a case of abnormality diagnosis of the high-frequency circuit 1, and is configured to measure at least one kind of measurement value of a resistance value between the bias terminals 42a and 43a, a voltage between the bias terminals 42a and 43a, and a current flowing between the bias terminals 42a and 43a.

For example, the measurement circuit 61 applies a constant direct current voltage to the inspection circuit 50 via the bias terminals 42a and 43a, measures the current flowing between the bias terminals 42a and 43a, and calculates the resistance value between the bias terminals 42a and 43a based on a measurement result.

Alternatively, the measurement circuit 61 may apply a constant direct current to the inspection circuit 50 via the bias terminals 42a and 43a, measure the voltage between the bias terminals 42a and 43a, and calculate the resistance value between the bias terminals 42a and 43a based on the measurement result.

Further, the measurement circuit 61 may calculate a value obtained by subtracting the known resistance values of the bias circuits 42 and 43 from the resistance value between the bias terminals 42a and 43a, as the resistance value of the inspection circuit 50.

The abnormality detection unit 62 detects whether or not at least one kind of abnormality including disconnection of the main lines 14 and 15, disconnection of a connection conductor described later, and a short circuit of the capacitor 32 occurs based on the measurement value measured by the measurement circuit 61.

For example, in a case where the capacitance of the capacitor 32 is C1 [pF] and the resistance value of the resistor 25 is R1 [Ω], the impedance of the inspection circuit 50 in a normal case is 1/{(1/R1)+ (jωC1)}, and a current corresponding to R1 flows between the bias terminals 42a and 43a.

On the other hand, in a case where there is a disconnection portion in the main lines 14 and 15 or the connection conductor, R1 is equivalent to infinity. Therefore, the impedance of the inspection circuit 50 under is 1/{(1/∞)+(jωC1)}, and a current does not flow between the bias terminals 42a and 43a.

Therefore, the abnormality detection unit 62 determines that at least one of the main lines 14 and 15 and the connection conductor is disconnected in a case where the resistance value measured by the measurement circuit 61 is a value corresponding to infinity.

In a case where the resistor 25 is not disposed in parallel with the capacitor 32, it is not possible to distinguish whether or not a current flows between the bias terminals 42a and 43a due to the direct current blocking effect of the capacitor 32 or whether or not a current flows between the bias terminals 42a and 43a due to the disconnection of the main lines 14 and 15.

In addition, in a case where the original capacitance of the capacitor 32 is C1 [pF] and the resistance value of the resistors 25 disposed in parallel is R1 [Ω], C1=∞ in a case where the capacitor 32 is short circuited. In this case, the impedance of the inspection circuit 50 is 1/{(1/R1)+(jω∞)}, and the current flows between the bias terminals 42a and 43a regardless of R1.

Therefore, the abnormality detection unit 62 determines that the capacitor 32 is short circuited in a case where the current measured by the measurement circuit 61 is not included in the current range assumed from the impedance of the inspection circuit 50 in a normal case.

The display unit 63 is configured by a display device such as a liquid crystal display (LCD) that displays a graphical user interface (GUI) such as a soft key resistance value, and displays the content of the abnormality detected by the abnormality detection unit 62.

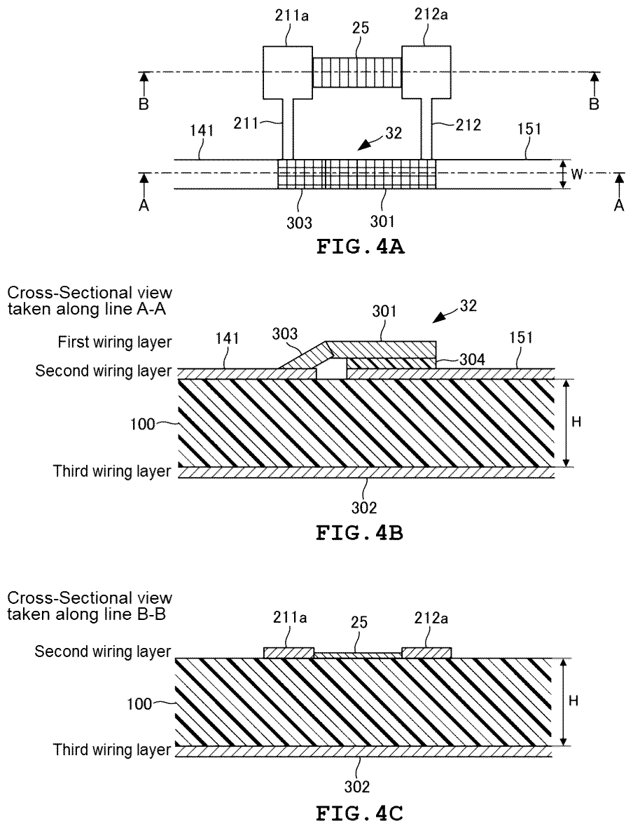

FIGS. 4A to 4C are diagrams showing a specific configuration example of the inspection circuit 50. FIG. 4A is a top view of the inspection circuit 50, FIG. 4B is a cross-sectional view taken along line A-A of FIG. 4A, and FIG. 4C is a cross-sectional view taken along line B-B of FIG. 4A.

As shown in FIG. 4B, the inspection circuit 50 has a multilayer structure consisting of three layers from the first wiring layer to the third wiring layer.

A metal layer 301 constituting one electrode of the capacitor 32 is provided on the first wiring layer above the dielectric substrate 100.

A first main line conductor 141 that constitutes a part of the main line 14, a second main line conductor 151 that constitutes a part of the main line 15, a first branch conductor 211 that constitutes a part of the branch line 21, and a second branch conductor 212 that constitutes a part of the branch line 22 are provided on the second wiring layer on the surface of the dielectric substrate 100. A part of the second main line conductor 151 constitutes the other electrode of the capacitor 32.

A ground conductor layer 302 constituting a part of each of the main line 14, the main line 15, the branch line 21, and the branch line 22 is provided on the third wiring layer on the back surface of the dielectric substrate 100 as a common radio frequency ground (RF ground) of these lines.

The metal layer 301 and the first main line conductor 141 are electrically connected to each other by an air bridge 303. In addition, a dielectric film 304 is provided between the metal layer 301 and a part of the second main line conductor 151. That is, the capacitor 32 is constituted by the metal layer 301, a part of the second main line conductor 151, and the dielectric film 304, and the first main line conductor 141 and the second main line conductor 151 are capacitively coupled to each other through the capacitor 32.

The first branch conductor 211 is branched from the first main line conductor 141, and is electrically connected to the metal layer 301, that serves as one terminal of the capacitor 32, and one end of the resistor 25 formed of a thin metal through the air bridge 303. The first branch conductor 211 is integrally formed with the first main line conductor 141.

The second branch conductor 212 is branched from the second main line conductor 151 and is electrically connected to the second main line conductor 151 that serves as the other terminal of the capacitor 32 and the other end of the resistor 25. The second branch conductor 212 is integrally formed with the second main line conductor 151.

The tip portions of the first branch conductor 211 and the second branch conductor 212 on the resistor 25 side are pads 211a and 212a having a shape wider than the width of the resistor 25. This is because, in a case where a thin film ceramic substrate is used as the dielectric substrate 100, the alignment accuracy of the film formation in the manufacturing process is low.

The line lengths of the branch line 21 and the branch line 22 from the main line 14 and the main line 15 of the transmission line 10 to the resistor 25 are an integer multiple of substantially ½ of the wavelength Ag of the high-frequency signal transmitted through the branch line 21 and the branch line 22, that is, an integer multiple of an electrical length of 180°. Here, the wavelength Ag means an effective wavelength in consideration of the wavelength shortening effect due to the dielectric properties of the dielectric substrate 100.

By setting the line lengths of the branch line 21 and the branch line 22 to an integer multiple of the electrical length 180°, the impedance of the path consisting of the resistor 25, the branch line 21, and the branch line 22 can be made sufficiently high as viewed from the main lines 11 to 18 of the transmission line 10.

In the configurations shown in FIGS. 4A to 4C, the portions of the pads 211a and 212a of the first branch conductor 211 and the second branch conductor 212 are capacitive. Therefore, it is apparent that the impedance design of the path consisting of the resistor 25, the branch line 21, and the branch line 22 needs to take into account the capacitance of the portions of the pads 211a and 212a.

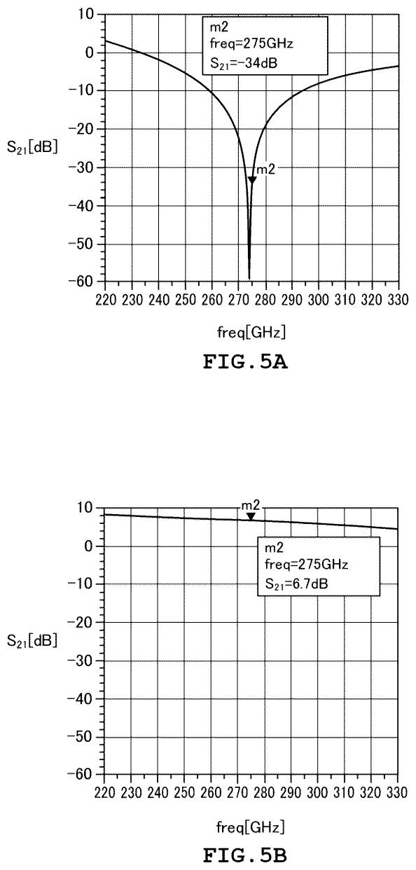

FIG. 5A is a graph showing a passage characteristic S₂₁ from the input terminal IN to the output terminal OUT of the high-frequency circuit 1 in a case where the line lengths of the branch line 21 and the branch line 22 in the inspection circuit 50 shown in FIGS. 4A to 4C are set to substantially ¼ of the wavelength λg of the high-frequency signal transmitted through the branch line 21 and the branch line 22.

On the other hand, FIG. 5B is a graph showing a pass characteristic S₂₁ from the input terminal IN to the output terminal OUT of the high-frequency circuit 1 in a case where the line lengths of the branch line 21 and the branch line 22 in the inspection circuit 50 shown in FIGS. 4A to 4C are set to substantially ½ of the wavelength λg of the high-frequency signal transmitted through the branch line 21 and the branch line 22.

In the graph of FIG. 5A, it can be seen that the pass gain at 275 GHz is −34 dB in a case where the line lengths of the branch line 21 and the branch line 22 are λg/4, and a large drop in the pass gain occurs in the vicinity of 274 GHZ.

On the other hand, in the graph of FIG. 5B, it can be seen that the pass gain at 275 GHz is 6.7 dB in a case where the line lengths of the branch line 21 and the branch line 22 are λg/2, and a favorable pass gain without a drop is obtained in the use frequency band of 220 GHz to 330 GHZ. That is, it can be confirmed that the impedance of the path consisting of the resistor 25, the branch line 21, and the branch line 22 is sufficiently high, so that the pass gain of the entire high-frequency circuit 1 is not adversely affected.

A specific configuration example of the inspection circuit 50 shown in FIGS. 4A to 4C is, for example, as follows.

The dielectric substrate 100 is a ceramic substrate having a substrate thickness H of 100 μm. The main line 14 and the main line 15 are microstrip lines in which the width W of the first main line conductor 141 and the second main line conductor 151 is 100 μm and the impedance is 50Ω. In addition, the width of the air bridge 303 is 100 μm, which is equal to the width W of the first main line conductor 141 and the second main line conductor 151. The pads 211a and 212a of the first branch conductor 211 and the second branch conductor 212 have a square shape in which one side is wider by 50 μm with respect to the width of the resistor 25.

Alternatively, the dielectric substrate 100 may be a resin substrate, a quartz glass substrate, or the like. For example, a fluororesin, a liquid crystal polymer, a BT resin (bismaleimide triazine resin), or the like can be used as the resin substrate. For example, the dielectric substrate 100 may be obtained by bonding a plurality of resin substrates, or may be a single-layer resin substrate.

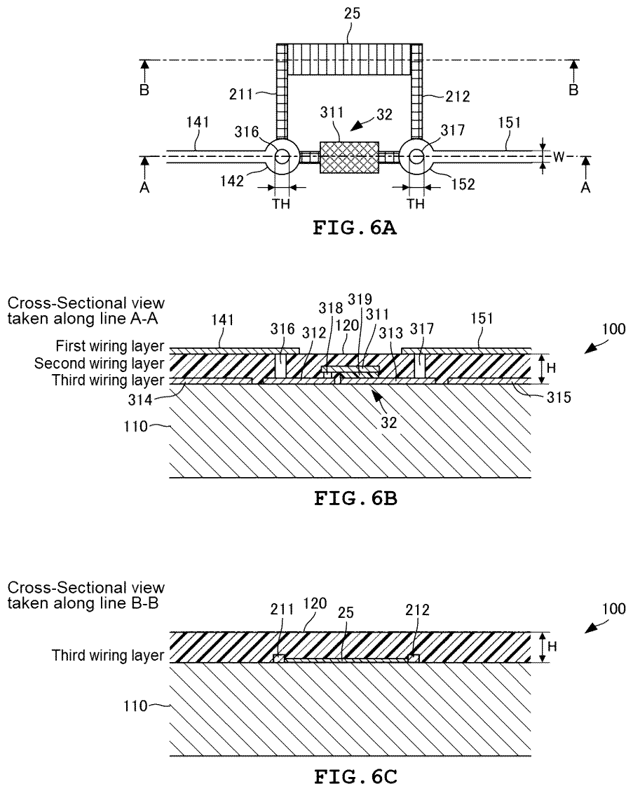

FIGS. 6A to 6C are diagrams showing an example in which the inspection circuit 50 is configured in a semiconductor integrated circuit (IC) as another configuration example of the inspection circuit 50. FIG. 6A is a top view of the inspection circuit 50, FIG. 6B is a cross-sectional view taken along line A-A of FIG. 6A, and FIG. 6C is a cross-sectional view taken along line B-B of FIG. 6A.

As shown in FIG. 6B, the dielectric substrate 100 consists of, for example, a lower substrate 110 and an upper substrate 120.

The lower substrate 110 is a semiconductor substrate consisting of, for example, various semiconductor materials such as GaAs, GaN, InP, or Si.

The upper substrate 120 consists of, for example, a single layer or a multilayer material having a relatively low dielectric constant, such as benzocyclobuteneutene (BCB) or SiO₂. In FIG. 6A, the upper substrate 120 is not shown.

As shown in FIG. 6B, the inspection circuit 50 has a multilayer structure consisting of three layers from the first wiring layer to the third wiring layer. That is, the inspection circuit 50 is configured by laminating a plurality of dielectric layers and a wiring layer on a surface side of the lower substrate 110 which is a semiconductor substrate.

A first main line conductor 141 constituting a part of the main line 14 and a second main line conductor 151 constituting a part of the main line 15 are provided on the first wiring layer on the surface of the upper substrate 120.

A metal layer 311 constituting one electrode of the capacitor 32 is provided on the second wiring layer in the upper substrate 120.

A first branch conductor 211 constituting a part of the branch line 21, a second branch conductor 212 constituting a part of the branch line 22, a first metal wire 312, a second metal wire 313, a ground conductor layer 314 constituting a part of the main line 14, and a ground conductor layer 315 constituting a part of the main line 15 are provided on the third wiring layer on the surface of the lower substrate 110.

The first branch conductor 211 and the first metal wire 312 are provided below the first main line conductor 141, and the second branch conductor 212 and the second metal wire 313 are provided below the second main line conductor 151.

The ground conductor layers 314 and 315 are provided as RF grounds of the main line 14 and the main line 15, respectively. Further, a ground conductor layer (not shown) constituting a part of each of the branch line 21 and the branch line 22 is provided in the third wiring layer as an RF ground.

A part of the second metal wire 313 constitutes the other electrode of the capacitor 32.

The first main line conductor 141 and the first metal wire 312 are electrically connected to each other by a first via hole 316. The first branch conductor 211 is integrally formed with the first metal wire 312 and is electrically connected to the first main line conductor 141 through the first via hole 316.

The second main line conductor 151 and the second metal wire 313 are electrically connected to each other by a second via hole 317. The second branch conductor 212 is integrally formed with the second metal wire 313 and is electrically connected to the second main line conductor 151 through the second via hole 317.

The first via hole 316, the second via hole 317, the first metal wire 312, and the second metal wire 313 constitute a connection conductor.

For example, the inner diameter TH of the first via hole 316 and the second via hole 317 is 2.4 μm, and the sizes of the pads 142 and 152 for the first via hole 316 and the second via hole 317 respectively formed at the tip portions of the first main line conductor 141 and the second main line conductor 151 are three times the inner diameter TH.

The first metal wire 312 and the metal layer 311 provided above the first metal wire 312 and the second metal wire 313 are electrically connected to each other by the third via hole 318.

The first via hole 316 and the second via hole 317 are configured by vapor-depositing or embedding a conductive material such as gold or copper in a through-hole that penetrates from the front surface to the back surface of the upper substrate 120. In addition, the third via hole 318 is configured by vapor-depositing or embedding a conductive material such as gold or copper in a through-hole that penetrates between the second wiring layer and the third wiring layer in the upper substrate 120. The through-holes of the first to third via holes 316 to 318 are formed by drilling the upper substrate 120 with a drill, a laser, or the like. The cross-sectional shape of the through-hole is usually a circle, but may have various shapes such as an ellipse, a square, or a rectangle.

In addition, a dielectric film 319 is provided between the metal layer 311 and a part of the second metal wire 313. That is, the capacitor 32 is constituted by the metal layer 311, a part of the second metal wire 313, and the dielectric film 319, and the first main line conductor 141 and the second main line conductor 151 are capacitively coupled to each other through the capacitor 32.

The first branch conductor 211 is configured to electrically connect the metal layer 311 that also serves as one terminal of the capacitor 32 and one end of the resistor 25 formed of a thin metal to each other through the third via hole 318. The second branch conductor 212 is configured to electrically connect the second metal wire 313 that serves as the other terminal of the capacitor 32 to the other end of the resistor 25.

The tip portions of the first branch conductor 211 and the second branch conductor 212 on the resistor 25 side have pad shapes substantially the same as the width of the resistor 25. This is because, in a case of manufacturing the dielectric substrate 100 by a semiconductor process, the alignment accuracy of film formation is high as compared with the configuration shown in FIG. 4A, and thus it is not required to dispose pads wider than the width of the resistor 25 at both ends.

As in the configuration of the inspection circuit 50 shown in FIG. 4A, the line lengths of the branch line 21 and the branch line 22 are an integer multiple of substantially ½ of the wavelength λg of the high-frequency signal transmitted through the branch line 21 and the branch line 22, that is, an integer multiple of an electrical length of 180°.

In the configuration shown in FIGS. 6A to 6C, for example, in a case where the upper substrate 120 consists of BCB, the thickness H thereof is 3 μm. The first to third wiring layers consist of, for example, gold. The main line 14 and the main line 15 are microstrip lines in which the width W of the first main line conductor 141 and the second main line conductor 151 is 5.3 μm and the impedance is 50Ω.

As described above, in the high-frequency circuit 1 according to the present embodiment, the resistor 25 is connected in parallel between the two terminals (electrodes) of the capacitor 32, and a measured value such as a resistance value, a voltage, or a current of the inspection circuit 50, which includes the parallel circuits of the capacitor 32 and the resistor 25, is measured through the bias terminals 42a and 43a.

Accordingly, the high-frequency circuit 1 and the abnormality detection method thereof according to the present embodiment can detect whether or not at least one kind of abnormality including disconnection of the main lines 14 and 15 of the transmission line 10 in the inspection circuit 50, disconnection of the connection conductor, and a short circuit of the capacitor 32 as the electronic component occurs with a small configuration.

In addition, the high-frequency circuit 1 and the abnormality detection method thereof according to the present embodiment have an advantage that the abnormality can be detected only by direct current measurement without using an expensive high-frequency measurement device.

In addition, in the high-frequency circuit 1 according to the present embodiment, the line lengths of the branch line 21 and the branch line 22 are integer multiples of substantially ½ of the wavelength λg of the high-frequency signal transmitted through the branch line 21 and the branch line 22.

Accordingly, in the high-frequency circuit 1 and the abnormality detection method thereof according to the present embodiment, the impedance of the path consisting of the resistor 25, the branch line 21, and the branch line 22 can be made sufficiently high as viewed from the main line 11 to 18 of the transmission line 10, so that the pass gain of the entire high-frequency circuit 1 is not adversely affected.

In addition, in the high-frequency circuit 1 according to the present embodiment, in a case where the electronic component electrically connected to the main lines 14 and 15 of the transmission line 10 is the capacitor 32, the abnormality detection unit 62 can detect whether or not any of the first via hole 316, the second via hole 317, the first metal wire 312, or the second metal wire 313 is disconnected.

### Second Embodiment

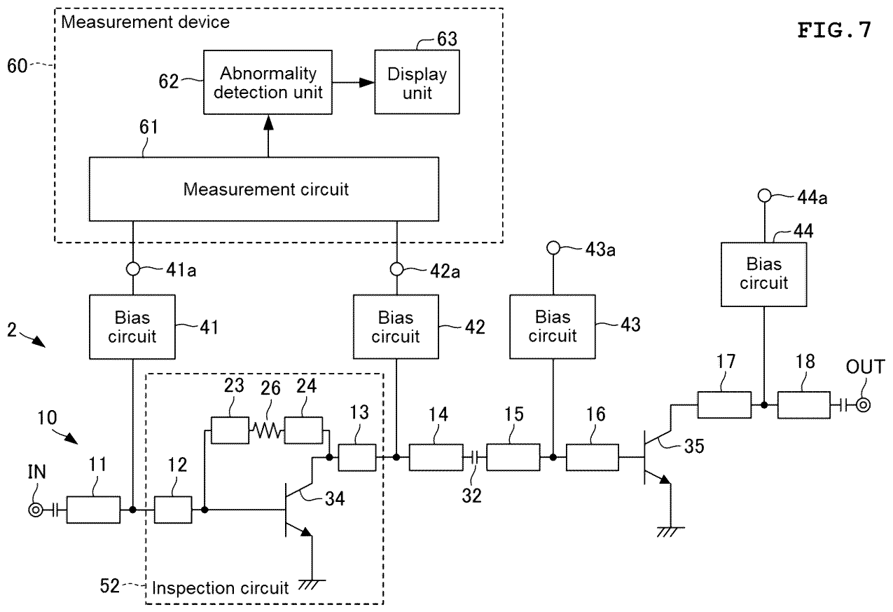

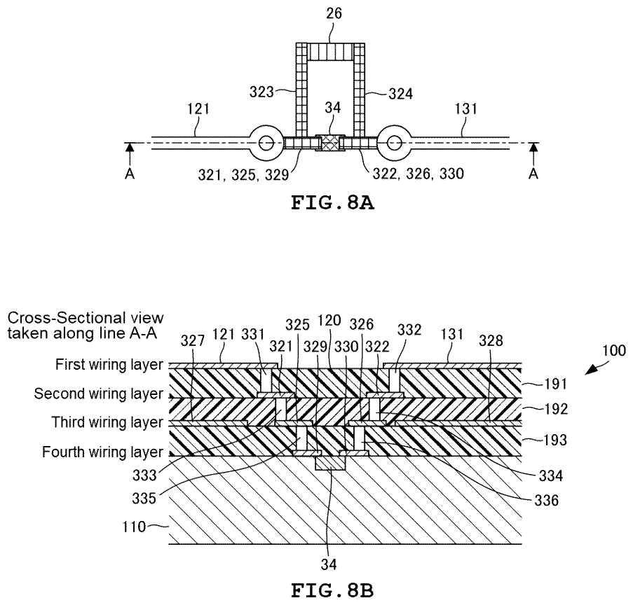

Next, a high-frequency circuit and an abnormality detection method thereof according to a second embodiment of the present invention will be described with reference to FIGS. 7 and 8. The same components as those in the first embodiment are designated by the same reference numerals, and the description thereof will be omitted as appropriate. Further, the description of the same operation as that of the first embodiment will be omitted as appropriate.

FIG. 7 is a diagram showing a configuration of a high-frequency circuit 2 of the present embodiment.

A base and a collector of the transistor 34 are inserted in series between the main line 12 as the first main line and the main line 13 as the second main line, and the base and the collector are electrically connected to the main line 12 and the main line 13, respectively. A resistor 26 is connected in parallel between the base and the collector of the transistor 34. The transistor 34 is an example of an electronic component provided in the high-frequency circuit 2, and the base and the collector of the transistor 34 correspond to two terminals through which direct current does not flow.

The main lines 12 and 13, the branch line 23 as the first branch line, the branch line 24 as the second branch line, the resistor 26, and the transistor 34 constitute the inspection circuit 52.

It is desirable that the resistance value of the resistor 26 does not affect the circuit characteristics of the entire high-frequency circuit 2, and may be, for example, substantially 10 times the resistance value of the base-emitter resistor of the transistor 34.

In the present embodiment, the bias terminals 41a and 42a are electrically connected to the main lines 12 and 13 via the bias circuits 41 and 42, respectively. The bias terminals 41a and 42a are disposed on both outsides of the main lines 12 and 13 constituting the inspection circuit 52, respectively, and serve as a pair of measurement terminals connected to the measurement device 60 in a case of abnormality diagnosis.

In the present embodiment, the measurement circuit 61 is connected to the bias terminals 41a and 42a in a case of abnormality diagnosis of the high-frequency circuit 2, and is configured to measure at least one kind of measurement value of a resistance value between the bias terminals 41a and 42a, a voltage between the bias terminals 41a and 42a, and a current flowing between the bias terminals 41a and 42a.

For example, the measurement circuit 61 applies a constant direct current voltage to the inspection circuit 52 via the bias terminals 41a and 42a, measures a current flowing between the bias terminals 41a and 42a, and calculates a resistance value between the bias terminals 41a and 42a based on a measurement result.

Alternatively, the measurement circuit 61 may apply a constant direct current to the inspection circuit 52 via the bias terminals 41a and 42a to measure a voltage between the bias terminals 41a and 42a, and calculate a resistance value between the bias terminals 41a and 42a based on the measurement result.

Further, the measurement circuit 61 may calculate a value obtained by subtracting the known resistance values of the bias circuits 41 and 42 from the resistance value between the bias terminals 41a and 42a, as the resistance value of the inspection circuit 52.

The abnormality detection unit 62 detects whether or not at least one kind of abnormality including disconnection of the main lines 12 and 13, disconnection of a connection conductor described later, and a short circuit of the transistor 34 occurs based on the measurement value measured by the measurement circuit 61.

For example, in a case where the base-collector capacitance of the transistor 34 is C2 [pF] and the resistance value of the resistor 26 is R2 [Ω], the impedance of the inspection circuit 52 in a normal case is 1/{(1/R2)+(jωC2)}, and a current corresponding to R2 flows between the bias terminals 41a and 42a.

On the other hand, a case where there is a disconnection portion in the main lines 12 and 13 or the connection conductor, R2 is equivalent to infinity. Therefore, the impedance of the inspection circuit 52 is 1/{(1/∞)+(jωC1)}, and a current does not flow between the bias terminals 41a and 42a.

Therefore, the abnormality detection unit 62 determines that at least one of the main lines 12 and 13 and the connection conductor is disconnected in a case where the resistance value measured by the measurement circuit 61 is a value corresponding to infinity.

In a case where the resistor 26 is not disposed in parallel with the base and the collector of the transistor 34, it is not possible to distinguish whether or not a current flows between the bias terminals 41a and 42a due to the direct current blocking effect of the transistor 34 or whether or not a current flows between the bias terminals 41a and 42a due to the disconnection of the main lines 12 and 13.

In addition, in a case where an original base-collector capacitance of the transistor 34 is C2 [pF] and the resistance value of the resistors 26 disposed in parallel is R2 [Ω], C2=∞ in a case where the base-collector of the transistor 34 is short circuited. In this case, the impedance of the inspection circuit 52 is 1/{(1/R2)+(jω∞)}, and the current flows between the bias terminals 41a and 42a regardless of R2.

Therefore, the abnormality detection unit 62 determines that the base-collector of the transistor 34 is short circuited in a case where the current measured by the measurement circuit 61 is not included in the current range assumed from the impedance of the inspection circuit 52 in a normal case.

FIGS. 8A and 8B are diagrams showing a specific configuration example of the inspection circuit 52 in the present embodiment. FIG. 8A is a top view of the inspection circuit 50, and FIG. 8B is a cross-sectional view taken along line A-A of FIG. 8A.

As shown in FIG. 8B, the dielectric substrate 100 consists of, for example, a lower substrate 110 and an upper substrate 120.

The lower substrate 110 is the same semiconductor substrate as in the first embodiment. The transistor 34 is formed on a surface side of the lower substrate 110.

As in the first embodiment, the upper substrate 120 consists of a single layer or a multilayer of a material having a relatively low dielectric constant, such as BCB or SiO₂. FIG. 8B shows an example in which the upper substrate 120 consists of three dielectric layers 191, 192, and 193. In FIG. 8A, the upper substrate 120 is not shown.

As shown in FIG. 8B, the inspection circuit 52 in the present embodiment has a multilayer structure consisting of four layers from the first wiring layer to the fourth wiring layer. That is, the inspection circuit 52 is configured by laminating a plurality of dielectric layers and a wiring layer on a surface side of the lower substrate 110 which is a semiconductor substrate.

The first main line conductor 121 constituting a part of the main line 12 and the second main line conductor 131 constituting a part of the main line 13 are provided on the first wiring layer on the surface of the dielectric layer 191.

A first metal wire 321 is provided below the first main line conductor 121, and a second metal wire 322 is provided below the second main line conductor 131, on the second wiring layer on the surface of the dielectric layer 192.

A third metal wire 325, a fourth metal wire 326, a ground conductor layer 327 constituting a part of the main line 12, and a ground conductor layer 328 constituting a part of the main line 13 are provided on the third wiring layer on the surface of the dielectric layer 193.

The third metal wire 325 is provided below the first metal wire 321, and the fourth metal wire 326 is provided below the second metal wire 322. The ground conductor layer 327 is provided below the first main line conductor 121, and the ground conductor layer 328 is provided below the second main line conductor 131.

In the examples shown in FIGS. 8A and 8B, the main line 12 and the main line 13 are microstrip lines having an impedance of 50Ω, and the ground conductor layers 327 and 328 are provided as RF grounds of the main line 12 and the main line 13, respectively.

The fourth wiring layer on the surface of the lower substrate 110 is provided with the first branch conductor 323 that constitutes a part of the branch line 23, the second branch conductor 324 that constitutes a part of the branch line 24, the fifth metal wire 329 that is electrically connected to the base which is one terminal of the transistor 34, and the sixth metal wire 330 that is electrically connected to the collector which is the other terminal of the transistor 34. An emitter of the transistor 34 is grounded to a ground conductor layer (not shown).

The first branch conductor 323 and the fifth metal wire 329 are provided below the third metal wire 325, and the second branch conductor 324 and the sixth metal wire 330 are provided below the fourth metal wire 326.

The first main line conductor 121 and the first metal wire 321 are electrically connected to each other by a first via hole 331. The second main line conductor 131 and the second metal wire 322 are electrically connected to each other by a second via hole 332.

The first metal wire 321 and the third metal wire 325 are electrically connected to each other by a third via hole 333. The second metal wire 322 and the fourth metal wire 326 are electrically connected to each other by a fourth via hole 334.

The third metal wire 325 and the fifth metal wire 329 are electrically connected to each other by a fifth via hole 335. The fourth metal wire 326 and the sixth metal wire 330 are electrically connected to each other by a sixth via hole 336.

The first via hole 331, the second via hole 332, the third via hole 333, the fourth via hole 334, the fifth via hole 335, the sixth via hole 336, the first metal wire 321, the second metal wire 322, the third metal wire 325, the fourth metal wire 326, the fifth metal wire 329, and the sixth metal wire 330 constitute a connection conductor.

The first branch conductor 323 is integrally formed with the fifth metal wire 329 and is electrically connected to the base of the transistor 34 and one end of the resistor 26 formed of the thin metal. The second branch conductor 324 is integrally formed with the sixth metal wire 330 and is electrically connected to the collector of the transistor 34 and the other end of the resistor 26.

The configurations of the first to sixth via holes 331 to 336 are the same as the configurations of the first to third via holes 316 to 318 in the first embodiment.

Similar to the inspection circuit 50 in the first embodiment, the line lengths of the branch line 23 and the branch line 24 are an integer multiple of substantially ½ of the wavelength λg of the high-frequency signal transmitted through the branch lines 23 and 24, that is, an integer multiple of the electrical length 180°.

In addition, the transistor 35 can also be configured to constitute the inspection circuit composed of the main lines 16 and 17, the first branch line track, the second branch line track, the resistor, and the transistor 35, similarly to the inspection circuit 52. In this case, in a case of abnormality diagnosis of the high-frequency circuit 2, the measurement circuit 61 of the measurement device 60 is connected between the bias terminals 43a and 44a as the pair of measurement terminals, so that the abnormality in the inspection circuit including the transistor 35 can be detected.

As described above, in the high-frequency circuit 2 according to the present embodiment, the resistor 26 is connected in parallel between the base and the collector of the transistor 34, and the measurement value such as the resistance value, the voltage, or the current of the inspection circuit 52 including the parallel circuit of the transistor 34 and the resistor 26 is measured through the bias terminals 41a and 42a.

Accordingly, the high-frequency circuit 2 and the abnormality detection method thereof according to the present embodiment can detect whether or not at least one kind of abnormality including disconnection of the main lines 12 and 13 of the transmission line 10 in the inspection circuit 52, disconnection of the connection conductor, or a short circuit of the transistor 34 as the electronic component occurs in a small configuration.

In addition, in the high-frequency circuit 2 according to the present embodiment, the abnormality detection unit 62 can detect whether or not any of the first via hole 331, the second via hole 332, the third via hole 333, the fourth via hole 334, the fifth via hole 335, the sixth via hole 336, the first metal wire 321, the second metal wire 322, the third metal wire 325, the fourth metal wire 326, the fifth metal wire 329, or the sixth metal wire 330 is disconnected.

### DESCRIPTION OF REFERENCE NUMERALS AND SIGNS

1, 2: High-Frequency Circuit
10: Transmission Line
11 to 18: Main Line
21 to 24: Branch Line
25, 26: Resistor
32: Capacitor
34, 35: Transistor
41, 42, 43, 44: Bias Circuit
41a, 42a, 43a, 44a: Bias Terminal
50, 52: Inspection Circuit
60: Measurement Device
61: Measurement Circuit
62: Abnormality Detection Unit
63: Display Unit
100: Dielectric Substrate
121, 141: First Main Line Conductor
131, 151: Second Main Line Conductor
211, 323: First Branch Conductor
212, 324: Second Branch Conductor
301, 311: Metal Layer
303: Air Bridge
304, 319: Dielectric Film
312, 321: First Metal Wire
313, 322: Second Metal Wire
316, 331: First Via Hole
317, 332: Second Via Hole
318, 333: Third Via Hole
325: Third Metal Wire
326: Fourth Metal Wire
329: Fifth Metal Wire
330: Sixth Metal Wire
334: Fourth Via Hole
335: Fifth Via Hole
336: Sixth Via Hole

What is claimed is:

1. A high-frequency circuit in which a transmission line for transmitting a high-frequency signal is provided on a dielectric substrate, the high-frequency circuit comprising:
an electronic component that has a plurality of terminals connected to a main line of the transmission line;
a resistor that is connected in parallel between two terminals, through which a direct current does not flow, among the plurality of terminals of the electronic component; and
a pair of measurement terminals that are connected to the main line, disposed respectively at both outsides of an inspection circuit which includes the resistor and the electronic component, and connected to a measurement device in a case of abnormality diagnosis,
wherein the measurement device includes
a measurement circuit that applies a direct current voltage or a direct current to the inspection circuit through the pair of measurement terminals and measures at least one kind of a measurement value of a resistance value between the pair of measurement terminals, a voltage between the pair of measurement terminals, and a current flowing between the pair of measurement terminals, and
an abnormality detection unit that detects whether or not disconnection of the main line or short circuit of the electronic component occurs, based on the measurement value measured by the measurement circuit.

2. The high-frequency circuit according to claim 1,
wherein the inspection circuit further includes
a first branch line that branches from the main line and connects one terminal of the two terminals of the electronic component to one end of the resistor, and
a second branch line that branches from the main line and connects the other terminal of the two terminals of the electronic component to the other end of the resistor, and
a line length of the first branch line and the second branch line from the main line to the resistor is an integer multiple of substantially ½ of a wavelength of the high-frequency signal transmitted through the first branch line and the second branch line.

3. The high-frequency circuit according to claim 2,
wherein the main line includes a first main line and a second main line that are capacitively coupled to each other via the electronic component,
a first main line conductor of the first main line, a second main line conductor of the second main line, a first branch conductor of the first branch line, and a second branch conductor of the second branch line are provided on a surface of the dielectric substrate,
the high-frequency circuit further includes
a metal layer that is provided above the dielectric substrate,
an air bridge that connects the first main line conductor to the metal layer, and
a dielectric film that is provided between the second main line conductor and the metal layer,
the first branch conductor is integrally formed with the first main line conductor,
the second branch conductor is integrally formed with the second main line conductor, and
the electronic component is a capacitor that includes the metal layer serving as the one terminal, the dielectric film, and the second main line conductor serving as the other terminal.

4. The high-frequency circuit according to claim 2,
wherein the main line includes a first main line and a second main line that are capacitively coupled to each other via the electronic component,
a first main line conductor of the first main line and a second main line conductor of the second main line are provided on a surface of the dielectric substrate,
the high-frequency circuit further includes
a first metal wire that is provided below the first main line conductor,
a second metal wire that is provided below the second main line conductor,
a metal layer that is provided above the first metal wire and the second metal wire,
a dielectric film that is provided between the second metal wire and the metal layer,
a first via hole that connects the first main line conductor to the first metal wire,
a second via hole that connects the second main line conductor to the second metal wire, and
a third via hole that connects the first metal wire to the metal layer,
a first branch conductor of the first branch line conductor provided below the first main line conductor is integrally formed with the first metal wire,
a second branch conductor of the second branch line conductor provided below the second main line conductor is integrally formed with the second metal wire,
the electronic component is a capacitor that includes the metal layer serving as the one terminal, the dielectric film, and the second metal wire serving as the other terminal, and
the abnormality detection unit further detects whether or not any of the first metal wire, the second metal wire, the first via hole, and the second via hole is disconnected.

5. The high-frequency circuit according to claim 2,
wherein the main line includes a first main line that is connected to the one terminal of the electronic component and a second main line that is connected to the other terminal of the electronic component,
a first main line conductor of the first main line and a second main line conductor of the second main line are provided on a surface of the dielectric substrate,
the high-frequency circuit further includes
a first metal wire that is provided below the first main line conductor,
a second metal wire that is provided below the second main line conductor,
a third metal wire that is provided below the first metal wire,
a fourth metal wire that is provided below the second metal wire,
a fifth metal wire that is provided below the third metal wire and connected to the one terminal,
a sixth metal wire that is provided below the fourth metal wire and connected to the other terminal, and
a plurality of via holes that connect the first main line conductor, the first metal wire, the third metal wire, and the fifth metal wire to each other, and connect the second main line conductor, the second metal wire, the fourth metal wire, and the sixth metal wire to each other,
a first branch conductor of the first branch line provided below the third metal wire is integrally formed with the fifth metal wire,
a second branch conductor of the second branch line provided below the fourth metal wire is integrally formed with the sixth metal wire,
the electronic component is an emitter-grounded transistor in which the one terminal is a base and the other terminal is a collector, and
the abnormality detection unit further detects whether or not any of the first metal wire, the second metal wire, the third metal wire, the fourth metal wire, the fifth metal wire, the sixth metal wire, and the plurality of via holes is disconnected.

6. An abnormality detection method of a high-frequency circuit, in which a transmission line for transmitting a high-frequency signal is provided on a dielectric substrate, including
an electronic component that has a plurality of terminals connected to a main line of the transmission line;
a resistor that is connected in parallel between two terminals, through which a direct current does not flow, among the plurality of terminals of the electronic component; and
a pair of measurement terminals that are connected to the main line, disposed respectively at both outsides of an inspection circuit which includes the resistor and the electronic component, and connected to a measurement device in a case of abnormality diagnosis,
wherein the measurement device includes
a measurement circuit that applies a direct current voltage or a direct current to the inspection circuit through the pair of measurement terminals and measures at least one kind of a measurement value of a resistance value between the pair of measurement terminals, a voltage between the pair of measurement terminals, and a current flowing between the pair of measurement terminals, and
an abnormality y detection unit that detects whether or not disconnection of the main line or short circuit of the electronic component occurs, based on the measurement value measured by the measurement circuit.
